(19) United States
(12) Patent Application Publication
(10) Pub. No.: US 2024/0057467 A1
(43) Pub. Date: Feb. 15, 2024

(54) FLEXIBLE SUBSTRATE, METHOD FOR MANUFACTURING SAME, AND DISPLAY PANEL

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Linshuang LI, Shenzhen, Guangdong (CN)

(73) Assignee: SHENZHEN CHINA STAR OPTOELECTRONICS SEMICONDUCTOR DISPLAY TECHNOLOGY CO., LTD., Shenzhen, Guangdong (CN)

(21) Appl. No.: 17/600,204

(22) PCT Filed: Aug. 11, 2021
(86) PCT No.: PCT/CN2021/111944

§ 371 Date: Sep. 30, 2021

(30) Foreign Application Priority Data
May 18, 2021 (CN) 202110537731.X

(51) Int. Cl. H10K 85/10; H10K 77/10; H10K 71/80

(52) U.S. Cl. CPC H10K 85/111; H10K 77/111; H10K 71/80

(57) ABSTRACT

A flexible substrate, a method for manufacturing same, and a display panel are provided. A constituent material of the flexible substrate includes a network polymer, and the network polymer includes a plurality of polymer chains and a plurality of connectors. Each of the polymer chains is formed by polymerizing at least a plurality of diamine monomers, and at least one of the diamine monomers includes —CF₃. Each of the connectors is connected between two corresponding polymer chains, and each of the polymer chains is connected to two polymer chains respectively through at least two connectors.

### FIELD OF INVENTION

The present invention relates to the field of display technologies, and in particular,

to manufacture of a display panel, and specifically, to a flexible substrate, a method for manufacturing same, and a display panel.

### BACKGROUND OF INVENTION

At present, flexible substrates are mainly made from colorless polyimide (CPI), which can achieve both flexibility and high transparency.

However, compared with a polyimide (PI) material, a CPI material includes a specific structure, so that the CPI material has a relatively low glass transition temperature and a relatively high thermal expansion coefficient. The relatively low glass transition temperature makes it difficult for a CPI film to adapt to a process temperature of a display panel, and the relatively high thermal expansion coefficient leads to relatively low dimensional stability of the CPI film. As a result, the quality of the CPI film is relatively poor, and the quality of the display panel is reduced.

To sum up, it is necessary to provide a flexible substrate, a method for manufacturing same, and a display panel, to improve the quality of the CPI film and the display panel.

### SUMMARY OF INVENTION

### Technical Problem

The present invention aims to provide a flexible substrate, a method for

manufacturing same, and a display panel, which resolves the problem of low quality of the CPI film caused by difficulty in adapting to the process temperature of the display panel and the low dimensional stability of the conventional CPI film.

### Technical Solution

Embodiments of the present invention provide a flexible substrate. A constituent material of the flexible substrate includes a network polymer, and the network polymer includes:
a plurality of polymer chains, each of the polymer chains being formed by polymerizing at least a plurality of diamine monomers, at least one of the diamine monomers including —CF₃; and
a plurality of connectors, each of the connectors being connected between two corresponding polymer chains, each of the polymer chains being connected to two polymer chains respectively through at least two connectors.

In an embodiment, each of the polymer chains includes at least two

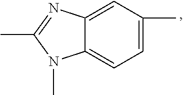

each of the connectors includes at least one methylene group, and each of the at least one methylene group in each of the connectors is connected to

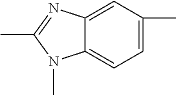

in at least one of the polymer chains.

In an embodiment, when the connector includes a plurality of methylene groups, two methylene groups at two ends of the connector are respectively connected to two

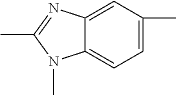

in the two corresponding polymer chains.

In an embodiment, each of the connectors includes at least one

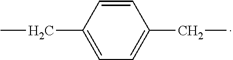

In an embodiment, each of the polymer chains is formed by polymerizing at least a plurality of dianhydride monomers and a plurality of diamine monomers.

In an embodiment, the plurality of dianhydride monomers used to generate the polymer chain are same or different, and the plurality of diamine monomers used to generate the polymer chain are same or different.

In an embodiment, at least one of the dianhydride monomers includes an alicyclic ring or a fluorine atom.

In an embodiment, glass transition temperatures of the network polymer and the flexible substrate are higher than 420° C.

An embodiment of the present invention provides a method for manufacturing a flexible substrate. The method includes:
coating a mixture on a base plate, the mixture including polyamide acid and a cross-linking agent, the polyamide acid including a benzimidazole structure, and the cross-linking agent including CH₂X—R₃—CH₂X, X being a halogen atom;
thermally imidizing the mixture to form a flexible film; and
peeling off the flexible film from the base plate to form a flexible substrate, wherein a constituent material of the flexible substrate includes a network polymer, the network polymer includes a plurality of polymer chains and a plurality of connectors, and each of the connectors is connected between two corresponding polymer chains, so that the network polymer has a three-dimensional structure.

In an embodiment, before the step of coating a mixture on a base plate, the method includes:
providing a first mixture, the first mixture including a solvent and a first substance, the first substance including a plurality of diamine monomers;
adding a second substance to the first mixture, so that the first substance reacts with the second substance to form the polyamide acid, the second substance including a plurality of dianhydride monomers; and
adding the cross-linking agent to the polyamide acid to form the mixture.

In an embodiment, before the step of thermally imidizing the mixture to form a flexible film, the method includes:
solidifying the mixture.

In an embodiment, the step of peeling off the flexible film from the base plate to form a flexible substrate includes:
injecting a laser from a side of the base plate away from the flexible film, to implement separation of the flexible film and the base plate.

An embodiment of the present invention provides a display panel. The display panel includes the flexible substrate according to at least one aspect described above.

In an embodiment, each of the polymer chains includes at least two

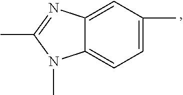

each of the connectors includes at least one methylene group, and each of the at least one methylene group in each of the connectors is connected to

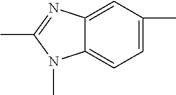

in at least one of the polymer chains.

In an embodiment, when the connector includes a plurality of methylene groups, two methylene groups at two ends of the connector are respectively connected to two

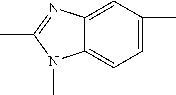

in the two corresponding polymer chains.

In an embodiment, each of the connectors includes at least one

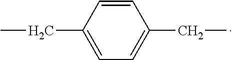

In an embodiment, each of the polymer chains is formed by polymerizing at least a plurality of dianhydride monomers and a plurality of diamine monomers.

In an embodiment, the plurality of dianhydride monomers used to generate the polymer chain are same or different, and the plurality of diamine monomers used to generate the polymer chain are same or different.

In an embodiment, at least one of the dianhydride monomers includes an alicyclic ring or a fluorine atom.

In an embodiment, glass transition temperatures of the network polymer and the flexible substrate are higher than 420° C.

### Beneficial Effects

The present invention provides a flexible substrate, a method for manufacturing same, and a display panel. A constituent material of the flexible substrate includes a network polymer. The network polymer includes: a plurality of polymer chains; and a plurality of connectors, each of the connectors being connected between two corresponding polymer chains. Each of the polymer chains is connected to two polymer chains respectively through at least two connectors. Each of the connectors in the present invention is connected between two corresponding polymer chains, so that two sides of each polymer chain are connected to at least two polymer chains. That is, each polymer chain is constrained by at least two corresponding polymer chains. Therefore, the network polymer with the three-dimensional structure is more stable, so that a higher temperature is required to disconnect a plurality of connectors and a plurality of polymer chains in order to destroy the network polymer. That is, the network polymer has a relatively high glass transition temperature and a relatively low thermal expansion coefficient. Finally, the quality of the flexible substrate and the quality of the display panel are improved.

### BRIEF DESCRIPTION OF DRAWINGS

The following describes specific implementations of the present disclosure in detail with reference to the accompanying drawings, to make the technical solutions and other beneficial effects of the present disclosure obvious.

FIG. 1 is a microstructure diagram of a flexible substrate according to an embodiment of the present invention.

FIG. 2 shows a chemical reaction formula of a nucleophilic substitution reaction according to an embodiment of the present invention.

FIG. 3 shows a chemical reaction formula of a plurality of dianhydride monomers, a plurality of diamine monomers, and a cross-linking agent according to an embodiment of the present invention.

FIG. 4 is a flowchart of an embodiment of a method for manufacturing a flexible substrate according to an embodiment of the present invention.

FIG. 5 is a flowchart of another embodiment of a method for manufacturing a flexible substrate according to an embodiment of the present invention.

### DETAILED DESCRIPTION OF PREFERRED EMBODIMENTS

The technical solutions of the embodiments of the present invention are clearly and completely described below with reference to the accompanying drawings of the embodiments of the present invention. Apparently, the described embodiments are merely some but not all of the embodiments of the present invention. All other embodiments obtained by a person skilled in the art based on the embodiments of the present invention without creative efforts shall fall within the protection scope of the present invention.

In the descriptions of the present invention, it should be understood that the directional or positional relationship indicated by the terms “end”, “away”, “corresponding”, and the like are based on the directional or positional relationship shown in the drawings, wherein “up” indicates that a surface is above an object, specifically referring to directly above, obliquely above, or upper surface, as long as the surface is above the level of the object. “Corresponding” means that there is a correspondence and specific positions of the two are not limited. The foregoing directional or positional relationship is only for convenience of describing the present invention and simplifying description, but does not indicate or imply that the mentioned apparatus or element needs to have a particular direction and be constructed and operated in the particular direction, and therefore cannot be understood as a limitation on the present invention. In addition, the terms “first” and “second” are used for descriptive purposes only and are not to be construed as indicating or implying relative importance or implicitly indicating the number of technical features indicated. Thus, features defined by “first” and “second” may explicitly or implicitly include one or more of the features. In the descriptions of the present disclosure, “a plurality of” means two or more, unless otherwise definitely and specifically limited. In addition, it should be noted that the drawings provide only the structures and steps closely related to the present invention, and omit some details that are not relevant to the present invention. The purpose is to simplify the drawings so that the points of the present invention are clear at a glance, rather than showing that an actual apparatus and method are exactly the same as the drawings, and the actual apparatus and method are not limited thereto.

Embodiment mentioned in the specification means that particular features, structures, or characteristics described with reference to the embodiment may be included in at least one embodiment of the present disclosure. The term appearing at different positions of the specification may not refer to the same embodiment or an independent or alternative embodiment that is mutually exclusive with another embodiment. A person skilled in the art explicitly or implicitly understands that the embodiments described in the specification may be combined with other embodiments.

The present invention provides a flexible substrate. The flexible substrate includes but is not limited to the following embodiments and various combinations between the following embodiments.

In an embodiment, as shown in FIG. 1, a constituent material of the flexible substrate includes a network polymer 10. The network polymer 10 includes: a plurality of polymer chains 101; and a plurality of connectors 102, each of the connectors 102 being connected between two corresponding polymer chains 101, each of the polymer chains 101 being connected to two polymer chains 101 respectively through at least two connectors 102. As can be understood, when there are no plurality of connectors 102, the plurality of polymer chains 101 are arranged in isolation. When the external environment changes, the plurality of polymer chains 101 may easily move, so that properties of a substance formed by the plurality of polymer chains 101 change, resulting in low stability of the material formed by the plurality of polymer chains 101. However, in the present embodiment, each of the connectors 102 is connected between two corresponding polymer chains 101, and each of the polymer chains 101 is connected to two polymer chains 101 respectively through at least two connectors 102, so that the network polymer 10 has a three-dimensional structure. That is, each of the polymer chains 101 is constrained by at least two corresponding polymer chains 101. When the external environment changes, every two correspondingly connected polymer chains 101 in the plurality of polymer chains 101 constrain each other. Therefore, the network polymer 10 with the three-dimensional structure is more stable, so that a higher temperature is required to disconnect a plurality of connectors 102 and a plurality of polymer chains 101 in order to destroy the network polymer 10. That is, the network polymer 10 has a relatively high glass transition temperature and a relatively low thermal expansion coefficient. Finally, the quality of the flexible substrate is improved.

The glass transition temperatures of the network polymer 10 and the flexible substrate can be higher than 420° C. A thermal expansion coefficient of a flexible film can be 15 ppm/° C., and a tensile strength of the flexible film may be greater than 100 mPa.

In an embodiment, each of the polymer chains 101 includes at least two

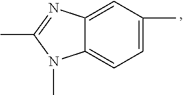

and each of the connectors 102 includes at least one methylene group.

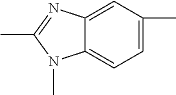

and the methylene group can be obtained through a nucleophilic substitution reaction of a substance containing a benzimidazole structure and a substance containing CH₂X—R₃—CH₂X respectively. As can be understood, an H atom connected to an N atom in the benzimidazole structure is more active and thus can be separated from the corresponding N atom. The methylene group formed after CH₂X—R₃—CH₂X loses a halogen atom may be connected to the N atom that loses the H atom in the benzimidazole structure, to form a substance containing both

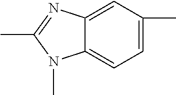

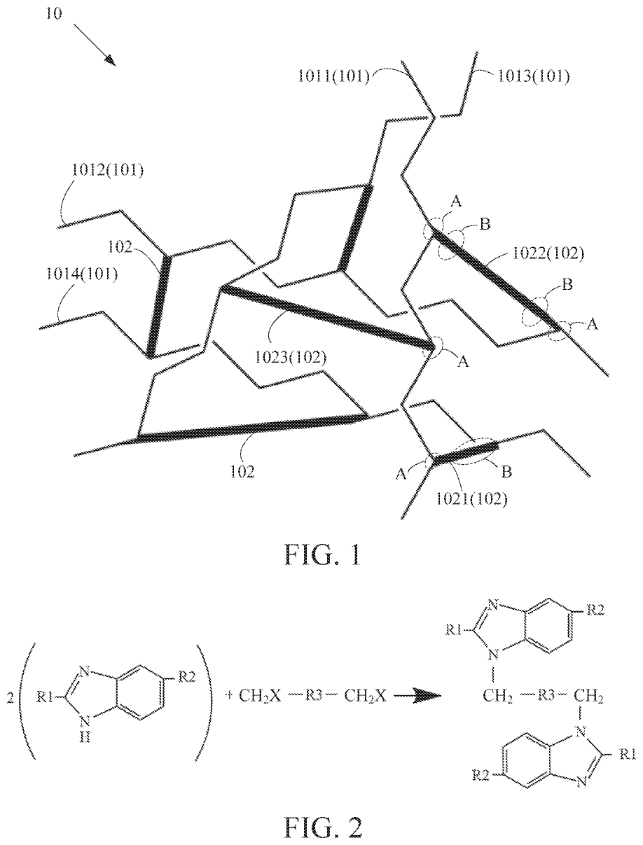

and the methylene group. Specifically, as shown in FIG. 2, the nucleophilic substitution reaction between a substance

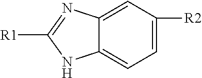

containing a benzimidazole structure and a substance containing CH₂X—R₃—CH₂X is used as an example for description, wherein R1 and R2 are group structures, R3 is a structure after the groups lose H atoms, and X is a halogen atom. The halogen atom can be a chlorine atom or a bromine atom. As can be understood, two

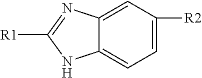

molecules may undergo the nucleophilic substitution reaction with a CH₂X—R₃—CH₂X molecule. Specifically, two halogen atoms in a CH₂X—R₃—CH₂X molecule can be replaced by two

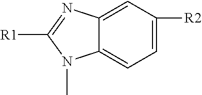

ionized in two

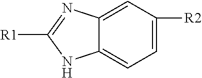

molecules to generate

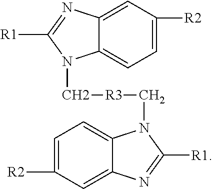

According to the analysis above, reactants corresponding to

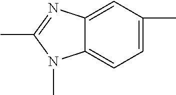

and the methylene group connected to each other in the network polymer 10 both contain active H atoms or halogens for the nucleophilic substitution reaction. Further, the methylene group has two vacancies that can connect two

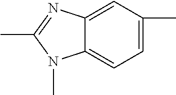

formed by two benzimidazole structures losing H atoms respectively. In addition, the methylene group is contained in the connector 102, and

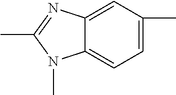

is contained in the polymer chain 101. That is, each of the connectors 102 can be connected to at least two polymer chains 101, so that the network polymer has a three-dimensional structure.

In an embodiment, when the connector 102 includes a plurality of methylene groups, two methylene groups at two ends of the connector 102 are respectively connected to two

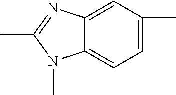

in the two corresponding polymer chains 101. Specifically, as shown in FIG. 1, each of the polymer chains 101 includes at least two A structures, the A structure is

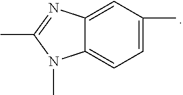

Each of the connectors 102 includes at least one B structure, and the B structure is a methylene group. The B structure at any end of each connector 102 is connected to the A structures in the corresponding polymer chains 101. As can be understood, for a connector 102 including a B structure, such as a connector 1021 in FIG. 1, two ends of the B structure in the connector 1021 are connected to an A structure in a polymer chain 1011 and an A structure in the polymer chain 1014 respectively. For a connector 102 including a plurality of B structures, such as a connector 1022 in FIG. 1, two B structures at two ends of the connector 1022 are respectively connected to the A structure in the polymer chain 1011 and the A structure in the polymer chain 1012. As can be understood, for a polymer chain 101 including three A structures, such as the polymer chain 1011 in FIG. 1, the three A structures in the polymer chain 1011 can be respectively connected to the connector 1022, the connector 1023, and the connector 1021, to connect the polymer chain 1012, the polymer chain 1013, and the polymer chain 1014. Similarly, a quantity of connectors 102 that may be connected to each polymer chain 101 is positively correlated with a quantity of A structures in the each polymer chain 101. A greater quantity of A structures in the polymer chain 101 indicates a more stable polymer chain 101, further improving the stability of the network polymer 10.

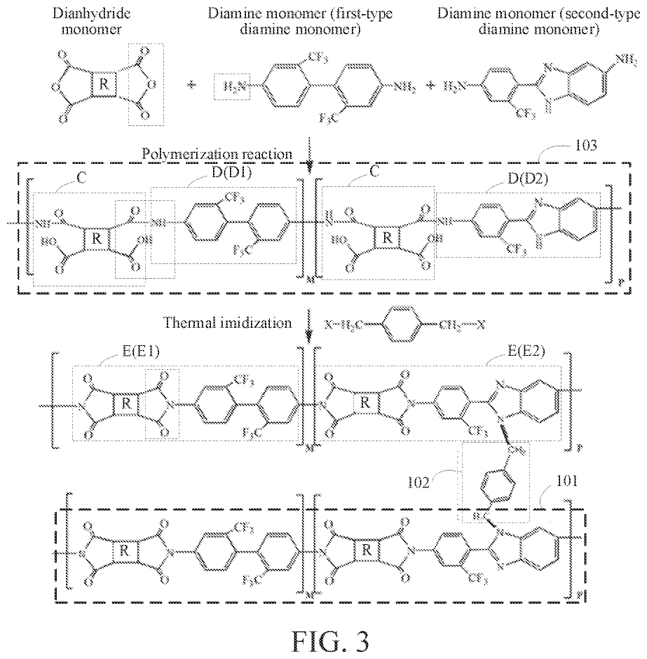

In an embodiment, as shown in FIG. 3, each of the connectors 102 includes at least one

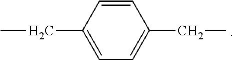

According to the analysis above, each of the connectors 102 is used to connect two corresponding polymer chains 101. The stability of the connector 102 determines the stability of the connection between the two corresponding polymer chains 101. The two methylene groups at two ends of

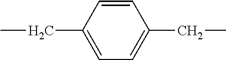

in the connector 102 are respectively connected to the two corresponding polymer chains 101. As can be understood, the

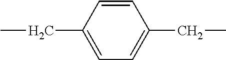

structure includes a benzene ring structure, that is, includes three covalent bonds and one ring structure. Firstly, a covalent bond is more stable than an ionic bond. Secondly, the ring structure makes two “paths” between the two corresponding polymer chains 101. Even if the ring structure is broken at one point, the connector 102 can still be connected between the two corresponding polymer chains 101. Therefore, the present embodiment can improve the stability of the connection between the two polymer chains 101, to improve the stability of the network polymer 10.

In an embodiment, as shown in FIG. 3, each of the polymer chains 101 is formed by polymerizing at least a plurality of dianhydride monomers and a plurality of diamine monomers. The plurality of dianhydride monomers used to generate the polymer chain 101 can be same or different, and the plurality of diamine monomers used to generate the polymer chain 101 can be same or different. Specifically, as shown in FIG. 3, first, a

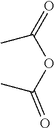

structure at the end of the dianhydride monomer reacts with an amino group at the end of the diamine monomer to form a

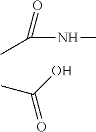

structure. A quantity of the dianhydride monomers may be same as that of the diamine monomers. That is, a plurality of dianhydride monomers may be in one-to-one correspondence with a plurality of diamine monomers, to undergo a polymerization reaction to generate alternately arranged C structures and D structures. The C structure is generated by a reaction of the dianhydride monomer, and the D structure is generated by a reaction of the diamine monomer. The alternately arranged C structures and D structures are then thermally imidized to form E structures including

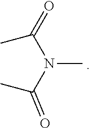

Moreover, the D structures further undergo a cross-linking reaction with other substances to form the connectors 102 connected between two corresponding polymer chains 101.

As can be understood, as shown in FIG. 3, the plurality of diamine monomers may include a first-type diamine monomer and a second-type of diamine monomer. Correspondingly, the D structure may be a D1 structure generated by a reaction of the first-type diamine monomer or a D2 structure generated by a reaction of the second-type diamine monomer. Correspondingly, the E structure may be an E1 structure generated by thermally imidizing the alternately arranged C structure and D1 structure, or an E2 structure generated by thermally imidizing the alternately arranged and connected C structure and D2 structure. According to the analysis above, each M of the C structures and M of the D1 structures may be thermally imidized to generate M of the E1 structures. Each P of the C structures and P of the D2 structures may be thermally imidized to generate P of the E2 structures. That is, each 2*(M +P) of the C structures, 2*M of the D1 structures, and 2*P of the D2 structures may generate two polymer chains 101 as shown in FIG. 3. Further, in combination with the description above, when the second-type diamine monomer includes the benzimidazole structure, the D2 structure generated by the second-type diamine monomer and the substance (for example,

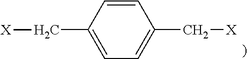

including CH₂X—R₃—CH₂X undergo a cross-linking reaction to generate the connector 102. The connector is connected between two

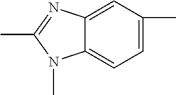

in two corresponding E2 structures.

In an embodiment, as shown in FIG. 3, at least one of the dianhydride monomers or at least one of the diamine monomers includes an alicyclic ring or a fluorine atom. As can be understood, the conventional flexible substrate usually presents brownish yellow and has low transmittance to visible light. In the present embodiment, an alicyclic ring or a fluorine atom is introduced into at least one of the dianhydride monomers or at least one of the diamine monomers, so that intramolecular and intermolecular forces can be reduced to reduce the formation of charge transfer complexes. Therefore, a certain orientation structure appears on a film surface, thereby improving the transparency of the flexible substrate to increase the transmittance to visible light. Specifically, when the dianhydride monomer includes an alicyclic ring or a fluorine atom, as shown in FIG. 3, the R structure in the dianhydride monomer may include at least one alicyclic ring or at least one fluorine atom. The R structure may be, but is not limited to, the following structures:

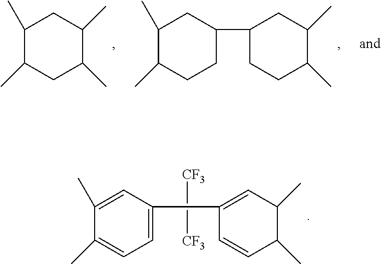

When the diamine monomer includes an alicyclic ring or a fluorine atom, as shown in FIG. 3, the diamine monomer may include CF₃, and the —CF₃ may be connected to the benzene ring. Certainly, the diamine monomer can further include an alicyclic ring.

The present invention provides a method for manufacturing a flexible substrate, to manufacture the flexible substrate as described above. The method includes but is not limited to the following embodiments and various combinations between the following embodiments.

In an embodiment, as shown in FIG. 4, the method may include, but is not limited to, steps of:

S1. Coat a mixture on a base plate, the mixture including polyamide acid and a cross-linking agent, the polyamide acid including a benzimidazole structure, and the cross-linking agent including CH₂X—R₃—CH₂X, X being a halogen atom. As can be understood, according to the analysis above,

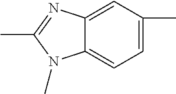

and the methylene group may be obtained through the nucleophilic substitution reaction of the substance containing the benzimidazole structure and the substance containing CH₂X—R₃—CH₂X respectively. In addition,

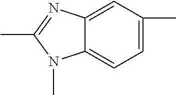

and the methylene group connected to each other in the network polymer 10 are contained in the polymer chain 101 and the connector 102 respectively. That is, the polyamide acid and the cross-linking agent may undergo a cross-linking reaction to generate the network polymer 10 with the three-dimensional structure, so that the network polymer 10 has a respectively high glass transition temperature and a respectively low thermal expansion coefficient. Finally, the quality of the flexible substrate is improved.

Specifically, as shown in FIG. 3, the polyamide acid can be a polymer 103 formed by the alternately arranged and connected C structures and D structures, that is, the benzimidazole structure may be included in the D structure. A structural formula of the cross-linking agent may be

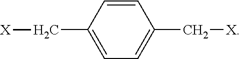

Further, the cross-linking agent includes at least one of dichloro-p-xylene and dibromo-p-xylene. According to the analysis above, the polyamide acid includes a benzimidazole structure, and may undergo a nucleophilic substitution reaction with CH₂X—R₃—CH₂X in the cross-linking agent, to generate the polymer chains 101 and the connectors 102 connected to each other.

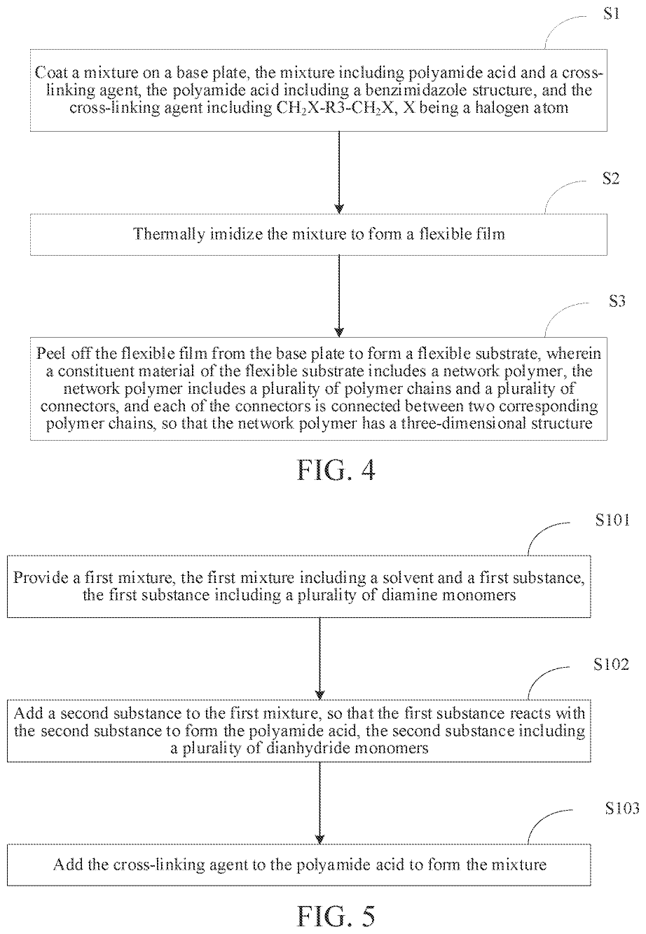

In an embodiment, as shown in FIG. 5, before step 51, the method can include, but is not limited to, steps of:

S101. Provide a first mixture, the first mixture including a solvent and a first substance, the first substance including a plurality of diamine monomers.

The plurality of diamine monomers in the first substance can be same or different, and the selection of the plurality of diamine monomers may refer to the relevant description above. Specifically, as shown in FIG. 3, the plurality of diamine monomers may include, but are not limited to, the first-type diamine monomer and the second-type diamine monomer. The solvent may be a polar aprotic solvent for dissolving the first mixture. Constituent materials of the solvent can be, but are not limited to, N-methylpyrrolidone, N, N-Dimethylacetamide, and N, N-dimethylformamide.

S102. Add a second substance to the first mixture, so that the first substance reacts with the second substance to form the polyamide acid, the second substance including a plurality of dianhydride monomers.

The plurality of dianhydride monomers in the second substance may be same or different, and the selection of the plurality of dianhydride monomers may refer to the relevant description above. Specifically, as shown in FIG. 3, the R structures in the plurality of diamine monomers can be, but are not limited to,

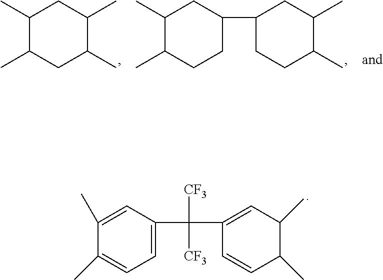

According to the analysis above, the plurality of diamine monomers in the first substance and the plurality of dianhydride monomers in the second substance undergo a polymerization reaction to generate the polyamide acid. A quantity of diamine monomers in the first substance can be the same as a quantity of dianhydride monomers in the second substance, to generate the polymer 103 formed by the alternately arranged and connected C structures and D structures. It should be noted that a solubility of the second substance is greater than that of the first substance. That is, the first substance is added to the solvent for dissolution, and then the second substance is added to the first mixture for the polymerization reaction.

S103. Add the cross-linking agent to the polyamide acid to form the mixture.

It should be noted that the cross-linking agent does not chemically react with the polyamide acid at room temperature. In this case, the two are mixed to form the mixture. According to the analysis above, as shown in FIG. 3, the quantity of connectors 102 is related to the quantity of CH₂X—R₃—CH₂X in the cross-linking agent. After the cross-linking reaction, each CH₂X—R₃—CH₂X may be connected to two corresponding polymer chains 101. Therefore, the cross-linking agent may include more CH₂X—R₃—CH₂X. Further, the quantity of CH₂X—R₃—CH₂X cannot be less than the quantity of polymer chains 101 minus one.

S2. Thermally imidizing the mixture to form a flexible film.

Specifically, the mixture on the base plate can be heated and dried by continuous or step-by-step heating, and thermal imidization is then implemented by heat treatment at a relatively high temperature. For example, the following operations may be performed on the mixture in sequence: drying at a first temperature for a first duration, drying at a second temperature for a second duration, . . . , and so on, until the temperature is increased to 400° C. for heat treatment, wherein the second temperature is higher than the first temperature. As can be understood, in the process of the thermal imidization. the nolvamide acid in the mixture is dehydrated and cyclized to form the

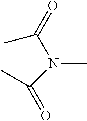

structure and further generate a plurality of polymer chains 101. In addition, the benzimidazole structure in the D structure also undergoes a cross-linking reaction with the cross-linking agent to generate the connector 102 connected between the two corresponding polymer chains 101, That is, the flexible film includes the network polymer 10.

The glass transition temperature of the flexible film may be higher than 420° C. A thermal expansion coefficient of the flexible film may be 15 ppm/° C., and a tensile strength of the flexible film may be greater than 100 mPa.

In an embodiment, before step S2, the method may include, but is not limited to, a step of solidifying the mixture. The temperature for solidify the mixture may be lower than 150° C., to avoid a chemical reaction. It should be noted that this step is used for removing the solvent in the mixture to improve a concentration of the polyamide acid and a concentration of the cross-linking agent in the mixture, which is conducive to subsequent polymerization reaction and cross-linking reaction.

S3. Peel off the flexible film from the base plate to form a flexible substrate, wherein a constituent material of the flexible substrate includes a network polymer, the network polymer includes a plurality of polymer chains and a plurality of connectors, and each of the connectors is connected between two corresponding polymer chains, so that the network polymer has a three-dimensional structure.

It should be noted that a plurality of film layers may be prepared on the flexible film before the flexible film is peeled off from the base plate. Specifically, the plurality of film layers may include, but are not limited to, a water oxygen barrier layer, a film transistor layer, a light-emitting element, and a packaging layer. A process including, but not limited to, a laser peeling process may be adopted to peel off the flexible film from the base plate. Specifically, a laser may be injected from a side of the base plate away from the flexible film, to implement separation of the flexible film and the base plate, thereby forming the flexible substrate. According to the analysis above, the plurality of connectors 102 in the flexible film connect the plurality of polymer chains 101. Every two correspondingly connected polymer chains 101 in the plurality of polymer chains 101 constrain each other to make the network polymer 10 more stable. Therefore, the flexible substrate has a relatively high glass transition temperature and a relatively low thermal expansion coefficient. For details, reference can be made to the relevant description of the flexible film above.

The present invention provides a display panel. The display panel includes the flexible substrate as described above. A constituent material of the flexible substrate includes a network polymer. The network polymer includes a plurality of polymer chains and a plurality of connectors. Each of the connectors is connected between two corresponding polymer chains, so that the network polymer has a three-dimensional structure. For the flexible substrate, the network polymer, the plurality of polymer chains, and the plurality of connectors, reference may be made to the relevant description above.

The present invention provides a flexible substrate, a method for manufacturing same, and a display panel. A constituent material of the flexible substrate includes a network polymer. The network polymer includes: a plurality of polymer chains; and a plurality of connectors, each of the connectors being connected between two corresponding polymer chains, each of the polymer chains being connected to two polymer chains respectively through at least two connectors. Each of the connectors in the present invention is connected between two corresponding polymer chains, so that two sides of each polymer chain are connected to at least two polymer chains. That is, each polymer chain is constrained by at least two corresponding polymer chains. Therefore, the network polymer with the three-dimensional structure is more stable, so that a higher temperature is required to disconnect a plurality of connectors and a plurality of polymer chains in order to destroy the network polymer. That is, the network polymer has a relatively high glass transition temperature and a relatively low thermal expansion coefficient. Finally, the quality of the flexible substrate and the quality of the display panel are improved.

The flexible substrate, the method for manufacturing same, and the display panel provided in the embodiments of the present invention are described in detail above. The principle and implementations of the present invention are described herein through specific examples. The description about the embodiments of the present invention is merely provided to help understand the technical solutions and core ideas of the present invention. A person of ordinary skill in the art should understand that, modifications may still be made to the technical solutions in the foregoing embodiments, or equivalent replacements may be made to some of the technical features; and such modifications or replacements will not cause the essence of corresponding technical solutions to depart from the scope of the technical solutions in the embodiments of the present invention.

What is claimed is:

1. A flexible substrate, wherein a constituent material of the flexible substrate comprises a network polymer, and the network polymer comprises:
a plurality of polymer chains, each of the polymer chains being formed by polymerizing at least a plurality of diamine monomers, at least one of the diamine monomers comprising —CF₃; and
a plurality of connectors, each of the connectors being connected between two corresponding polymer chains, each of the polymer chains being connected to two polymer chains respectively through at least two connectors.

2. The flexible substrate as claimed in claim 1, wherein each of the polymer chains comprises at least two 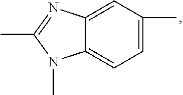
each of the connectors comprises at least one methylene group, and each of the at least one methylene group in each of the connectors is connected to 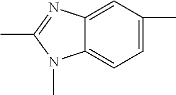
in at least one of the polymer chains.

3. The flexible substrate as claimed in claim 2, wherein when the connector comprises a plurality of methylene groups, two methylene groups at two ends of the connector are respectively connected to two 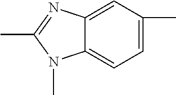
in the two corresponding polymer chains.

4. The flexible substrate as claimed in claim 2, wherein each of the connectors comprises at least one

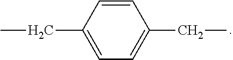

5. The flexible substrate as claimed in claim 1, wherein each of the polymer chains is formed by polymerizing at least a plurality of dianhydride monomers and a plurality of diamine monomers.

6. The flexible substrate as claimed in claim 5, wherein the plurality of dianhydride monomers used to generate the polymer chain are same or different, and the plurality of diamine monomers used to generate the polymer chain are same or different.

7. The flexible substrate as claimed in claim 5, wherein at least one of the dianhydride monomers comprises an alicyclic ring or a fluorine atom.

8. The flexible substrate as claimed in claim 1, wherein glass transition temperatures of the network polymer and the flexible substrate are higher than 420° C.

9. A method for manufacturing a flexible substrate, wherein the method is used for manufacturing the flexible substrate as claimed in claim 1 and comprises:
coating a mixture on a base plate, the mixture comprising polyamide acid and a cross-linking agent, the polyamide acid comprising a benzimidazole structure, and the cross-linking agent comprising CH₂X—R₃—CH₂X, X being a halogen atom;
thermally imidizing the mixture to form a flexible film; and
peeling off the flexible film from the base plate to form a flexible substrate, wherein a constituent material of the flexible substrate comprises a network polymer, the network polymer comprises a plurality of polymer chains and a plurality of connectors, and each of the connectors is connected between two corresponding polymer chains, so that the network polymer has a three-dimensional structure.

10. The method for manufacturing a flexible substrate as claimed in claim 9, wherein before the step of coating a mixture on a base plate, the method comprises:
providing a first mixture, the first mixture comprising a solvent and a first substance, the first substance comprising a plurality of diamine monomers;
adding a second substance to the first mixture, so that the first substance reacts with the second substance to form the polyamide acid, the second substance comprising a plurality of dianhydride monomers; and
adding the cross-linking agent to the polyamide acid to form the mixture.

11. The method for manufacturing a flexible substrate as claimed in claim 9, wherein before the step of thermally imidizing the mixture to form a flexible film, the method comprises:
solidifying the mixture.

12. The method for manufacturing a flexible substrate as claimed in claim 9, wherein the step of peeling off the flexible film from the base plate to form a flexible substrate comprises:
injecting a laser from a side of the base plate away from the flexible film, to implement separation of the flexible film and the base plate.

13. A display panel, comprising the flexible substrate as claimed in claim 1.

14. The display panel as claimed in claim 13, wherein each of the polymer chains comprises at least two 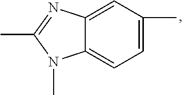
each of the connectors comprises at least one methylene group, and each of the at least one methylene group in each of the connectors is connected to 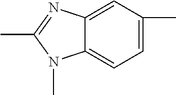
in at least one of the polymer chains.

15. The display panel as claimed in claim 14, wherein when the connector comprises a plurality of methylene groups, two methylene groups at two ends of the connector are respectively connected to two 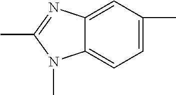
in the two corresponding polymer chains.

16. The display panel as claimed in claim 14, wherein each of the connectors comprises at least one

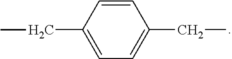

17. The display panel as claimed in claim 13, wherein each of the polymer chains is formed by polymerizing at least a plurality of dianhydride monomers and a plurality of diamine monomers.

18. The display panel as claimed in claim 17, wherein the plurality of dianhydride monomers used to generate the polymer chain are same or different, and the plurality of diamine monomers used to generate the polymer chain are same or different.

19. The display panel as claimed in claim 17, wherein at least one of the dianhydride monomers comprises an alicyclic ring or a fluorine atom.

20. The display panel as claimed in claim 13, wherein glass transition temperatures of the network polymer and the flexible substrate are higher than 420° C.
